(19) United States
(12) Patent Application Publication
(10) Pub. No.: US 2026/0206208 A1
(43) Pub. Date: Jul. 16, 2026

(54) SEMICONDUCTOR DEVICE

(71) Applicant: NANYA TECHNOLOGY CORPORATION, New Taipei City (TW)

(72) Inventors: Ying-Cheng Chuang, New Taipei City (TW); Chung-Lin Huang, New Taipei City (TW)

(73) Assignee: NANYA TECHNOLOGY CORPORATION, New Taipei City (TW)

(21) Appl. No.: 19/019,534

(22) Filed: Jan. 14, 2025

(51) Int. Cl. H10B 12/00; H10D 30/67

(52) U.S. Cl. CPC H10B 12/315; H10B 12/488; H10D 30/6755

(57) ABSTRACT

A semiconductor device is provided. The semiconductor device includes a semiconductor substrate, a capacitor structure, and a word line. The capacitor structure is disposed over the semiconductor substrate. The word line is disposed above the capacitor structure.

### BACKGROUND

### Technical Field

This present invention relates to a device, and in particular to a semiconductor device.

### Description of Related Art

Recently, the use of IGZO transistor in the semiconductor device is increased due to its low leakage current. In memory industry, the IGZO transistor is directly formed on the semiconductor substrate and connected to the capacitor to form memory array, and the core circuit and/or peripheral circuit of the semiconductor device is formed on the semiconductor substrate and arranged side by side with the memory array. This result in a large size of the semiconductor device. With the industry's demand for device size reduction, how to reduce device size is currently a problem that needs to be solved.

### SUMMARY

The present invention provides a semiconductor device, which has reduced size.

The semiconductor device of the present invention includes a semiconductor substrate, a capacitor structure, and a word line. The capacitor structure is disposed over the semiconductor substrate. The word line is disposed above the capacitor structure.

In an embodiment of the semiconductor device of the present invention, the semiconductor device further includes a channel structure disposed on the capacitor structure.

In an embodiment of the semiconductor device of the present invention, a material of the channel structure comprises a semiconductor oxide.

In an embodiment of the semiconductor device of the present invention, the semiconductor device further includes a gate oxide layer disposed between the word line and the channel structure.

In an embodiment of the semiconductor device of the present invention, the channel structure extending through the word line.

In an embodiment of the semiconductor device of the present invention, an extension direction of the channel structure is perpendicular to a top surface of the semiconductor substrate.

In an embodiment of the semiconductor device of the present invention, the channel structure is in direct contact with a top electrode of the capacitor structure.

In an embodiment of the semiconductor device of the present invention, the top electrode of the capacitor structure comprises a conductive oxide layer.

In an embodiment of the semiconductor device of the present invention, the semiconductor device further includes a landing pad disposed over the word line, wherein the channel structure is connected between the landing pad and the capacitor structure.

In an embodiment of the semiconductor device of the present invention, the landing pad comprises a conductive oxide layer.

The present invention includes a capacitor structure between the plurality of word lines and the semiconductor substrate. Since the plurality of word lines is disposed over the capacitor structure, some peripheral circuits or core circuits of the semiconductor device could be formed between the semiconductor substrate and the capacitor structure to make efficient use of space, and thereby the size of the semiconductor device can be reduced.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a semiconductor device according to an embodiment of the present invention.

FIGS. 2 to 16, FIG. 17A, FIG. 17B and FIGS. 18 to 20 are schematic views of a method of forming a semiconductor device according to an embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

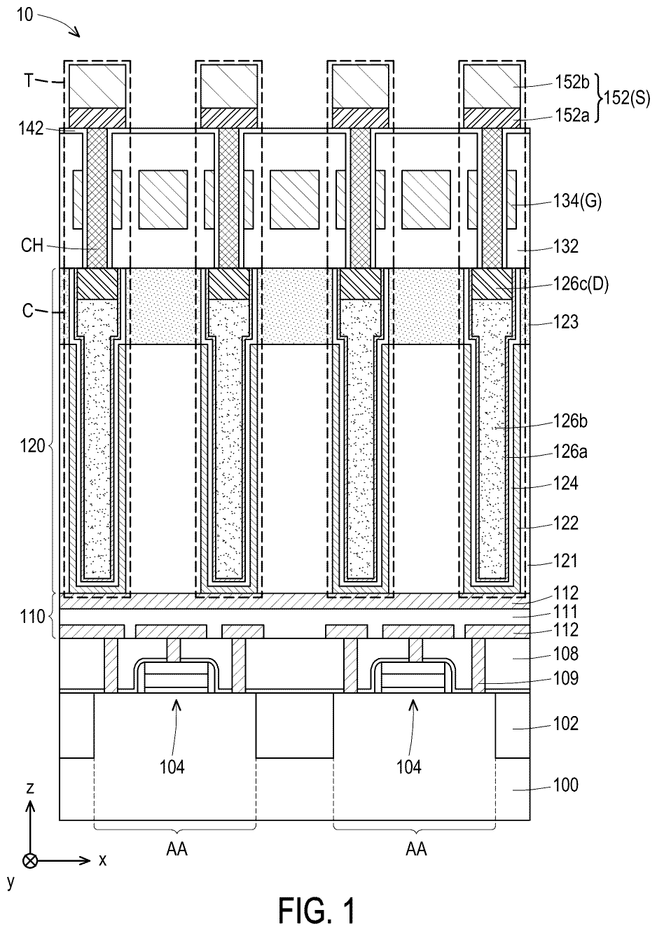

FIG. 1 is a schematic cross-sectional view of a semiconductor device according to an embodiment of the present invention.

Referring to FIG. 1, a semiconductor device 10 includes a semiconductor substrate 100, a capacitor structure 120 and a plurality of word lines 134. The capacitor structure 120 is disposed over the semiconductor substrate 100. The plurality of word lines 134 is disposed above the capacitor structure 120. That is, the capacitor structure 120 is located between the plurality of word lines 132 and the semiconductor substrate 100. In some embodiments, the plurality of word lines 134 is arranged along x direction and extends along y direction. In some embodiments, x direction is perpendicular to y direction.

In some embodiments, the semiconductor substrate 100 is a silicon substrate, a germanium substrate, a silicon germanium substrate or other suitable semiconductor substrates. In some embodiments, doping regions or well regions (not shown) may be formed in the semiconductor substrate 100. The doping regions or well regions may be p type or n type, which is not limited.

In some embodiments, shallow trench isolations 102 are formed in the semiconductor substrate 100 to define the active area AA of the semiconductor substrate 100.

In some embodiments, the semiconductor device 10 further includes active devices 104 on active area AA of the semiconductor substrate 100. In some embodiments, the active devices 104 may be transistors, diodes or other suitable active devices. In some embodiments, the semiconductor device 10 may include passive devices (not shown) formed on the semiconductor substrate 100.

In some embodiments, the semiconductor device 10 further includes an interconnect structure 110 on the semiconductor substrate 100. The interconnect structure 110 is configured to electrically connect to the devices (such as active devices 104) disposed on the semiconductor substrate 100 and/or the devices (such as transistors T described below) disposed above the capacitor structure 120. In some embodiments, the interconnect structure 110 and the active devices 104 may constitute a portion of peripheral circuits or core circuits of the semiconductor device 10.

In some embodiments, the interconnect structure 110 includes conductive layers 112 and a dielectric layer 111 stacked alternatively on the semiconductor substrate 100, and conductive vias (not shown) connected between adjacent conductive layers 112. Please note that FIG. 1 schematically shows two conductive layers 112 and one dielectric layer 111, but the invention is not limited thereto. The number of layers of the conductive layer 112 and the dielectric layer 111 is not limited and can be adjusted by the actual need.

In some embodiments, the capacitor structure 120 includes a plurality of capacitors C disposed in a dielectric layer 121 and a hard mask layer 123, and arranged along x direction, where the hard mask layer 123 is disposed on the dielectric layer 121. The capacitor C may be, for example, a single-side insulator capacitor (as shown in FIG. 1), a double-side insulator capacitor (not shown) or other suitable type of capacitors.

In FIG. 1, each capacitor C includes a bottom electrode 122, an insulator 124 and a top electrode 126. The bottom electrode 122 is disposed in the dielectric layer 121 and has a U shape in cross-sectional view. An outer surface of the bottom electrode 122 is in direct contact with the dielectric layer 121. The top electrode 126 is disposed on an inner surface of the bottom electrode 122. The insulator 124 is located between the bottom electrode 122 and the top electrode 126. In other words, the bottom electrode 122 is located between the dielectric layer 121 and the insulator 124.

In some embodiments, the insulator 124 and the top electrode 126 also extend into the hard mask layer 123, so that a portion of the insulator 124 is located between the hard mask layer 123 and the top electrode 126.

In some embodiments, the bottom electrode 122 is a single layer structure, but it is not limited thereto. In other embodiments, the bottom electrode 122 may be a multi-layers structure. In some embodiments, a material of the bottom electrode 122 includes metals (such as Cu, W, Al, Ti, alloy thereof or the like), metal nitrides (such as TiN or the like), conductive oxides (such as indium tin oxide (ITO) or the like), poly-silicon or other suitable conductive materials.

In some embodiments, the insulator 124 may be a single layer structure or a multi-layers structure, which is not limited. In some embodiments, a material of the insulator 124 includes SiO₂, ZrO₂, Al₂O₃, HfO₂, TiO₂, a combination thereof or other suitable high-k dielectric materials.

In some embodiments, the top electrode 126 is a multi-layers structure, but it is not limited thereto. In other embodiments, the top electrode 126 may be a single layer structure. In some embodiments, a material of the top electrode 126 includes metals (such as Cu, W, Al, Ti, alloy thereof or the like), metal nitrides (such as TiN or the like), conductive oxides (such as indium tin oxide (ITO) or the like), poly-silicon or other suitable conductive materials.

In some embodiments, the top electrode 126 includes a first conductive layer 126a, a second conductive layer 126b and a third conductive layer 126c. The first conductive layer 126a is conformally disposed on an inner side of the insulator 124. The second conductive layer 126b is disposed on the first conductive layer 126a and extends into the dielectric layer 121 and a portion of the hard mask layer 123. The third conductive layer 126c is disposed on the second conductive layer 126b and extends into a portion of the hard mask layer 123. The first conductive layer 126a, the second conductive layer 126b and the third conductive layer 126c have different materials. In some embodiments, the first conductive layer 126a may include TiN, the second conductive layer 126b may include poly-silicon, and the third conductive layer 126c may include ITO.

In some embodiments, a top surface of the third conductive layer 126c is substantially level with a top surface of the hard mask layer 123, a top surface of the insulator 124 and a top surface of the first conductive layer 126a.

In some embodiments, the semiconductor device 10 further includes a dielectric layer 132 disposed on the capacitor structure 120, a plurality of transistors T disposed in the dielectric layer 132 and landing pads 152 disposed over the dielectric layer 132. The plurality of transistors T is corresponding to the plurality of capacitors C.

In some embodiments, each landing pads 152 includes a multi-layers structure and the multi-layers structure includes a first conductive layer 152a disposed on the dielectric layer 132 and a second conductive layer 152b disposed on the first conductive layer 152a. A material of the first conductive layer 152a is different from a material of the second conductive layer 152b. In some embodiments, the material of the first conductive layer 152a includes conductive oxides (such as indium tin oxide (ITO) or the like) or other suitable conductive materials. The material of the second conductive layer 152b includes metals (such as Cu, W, Al, Ti, alloy thereof or the like) or other suitable conductive materials. However, the invention is not limited. In other embodiments, the landing pads 152 may be a single layer structure.

In some embodiments, the plurality of transistors T each includes a gate electrode G, a source electrode S, a drain electrode D, a channel structure CH and a gate dielectric layer 142. The gate electrode G may be composed of a portion of the word line 134, and is disposed in the dielectric layer 132. That is, the gate electrode G or the word line 134 is surrounded by the dielectric layer 132. The channel structure CH is disposed over the capacitor structure 120 and penetrates through the dielectric layer 132 and the word line 134 to physically connect to the third conductive layer 126c of the top electrode 126 of the capacitor C. That is, the channel structure CH is in direct contact with the top electrode 126 of the capacitor C. The gate dielectric layer 142 is located between the word line 134 (or the gate G) and the channel structure CH. The source electrode S and the drain electrode D are located at two opposite ends of the channel structure CH.

In some embodiments, the source electrode S is located on a top end of the channel structure CH and may be composed of the landing pad 152. The drain electrode D is located on a bottom end of the channel structure CH and may be composed of the third conductive layer 126c of the capacitor C. That is, the channel structure CH is connected between the landing pad 152 and the capacitor structure 120. The third conductive layer 126c may be a common electrode for the transistor T and the capacitor C, so that the transistor T may be electrically connected to the capacitor C.

In some embodiments, the transistor T is a vertical type transistor. An extension direction (such as z direction in FIG. 1) of the channel structure CH is perpendicular to a top surface of the semiconductor substrate 100. The top surface of the semiconductor substrate 100 may be in a x-y plane formed by x direction and y direction, and the z direction is perpendicular to the x direction and y direction.

In some embodiments, a material of the channel structure CH includes a semiconductor oxide, for example, indium gallium zinc oxide (IGZO) or the like, such that the subthreshold leakage of the transistor T is low, and thereby improving the data retention of the semiconductor device 10. However, the invention is not limited. In other embodiments, the channel structure CH may be other semiconductor materials, such as silicon, germanium, silicon germanium, or the like.

In some embodiments, the plurality of transistors T is electrically connected to bit lines (not shown) through the landing pads 152. The bit lines may be disposed over the plurality of transistors T or disposed in the interconnect structure 110, depending on the routing design.

In some embodiments, the landing pads 152 may be electrically connected to the interconnect structure 110 through additional routing circuits (not shown) formed between the interconnect structure 110 and the landing pads 152. For example, the additional routing circuits may be formed in the dielectric layer 121, and the additional routing circuits may be adjacent to at least one side of the capacitor structure 120.

Since the plurality of word lines 134 is disposed over the capacitor structure 120, some peripheral circuits or core circuits (including active devices 104 and interconnect structure 110) of the semiconductor device 10 could be formed between the semiconductor substrate 100 and the capacitor structure 120 to make efficient use of space, and thereby the size of the semiconductor device can be reduced.

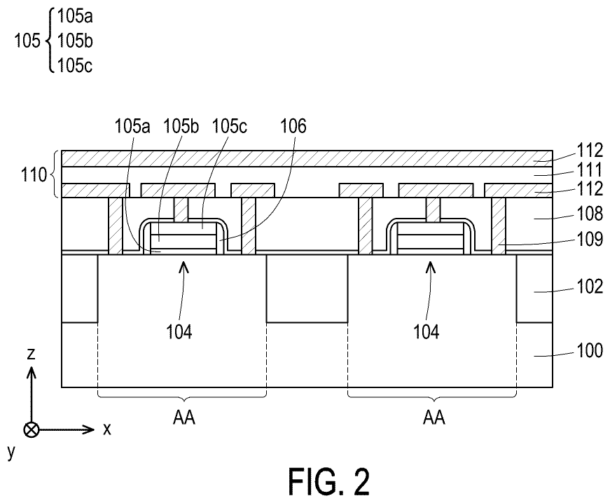

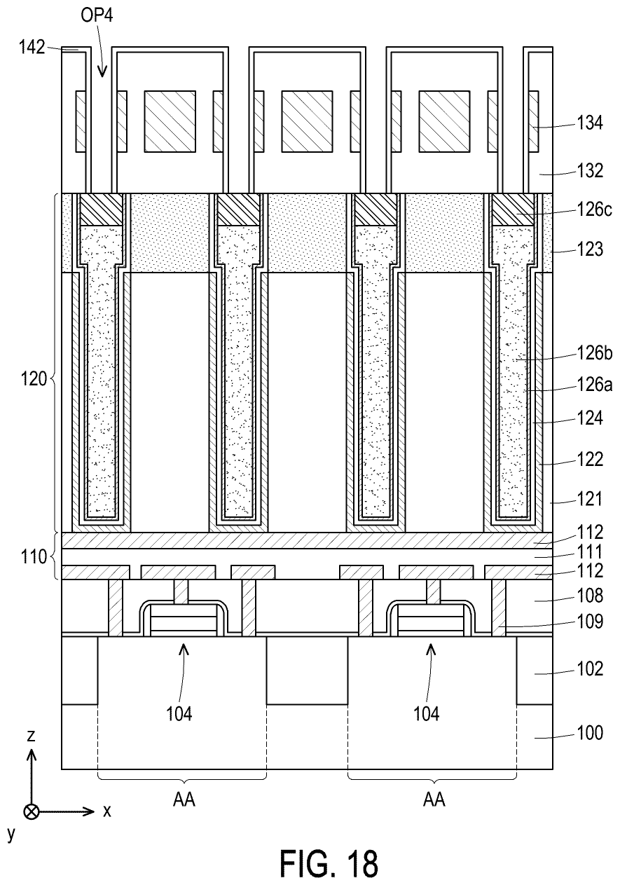

FIGS. 2 to 17, FIG. 18A, FIG. 18B and FIGS. 19 to 21 are schematic views of a method of forming a semiconductor device according to an embodiment of the present invention. FIGS. 2 to 17, FIG. 18A and FIGS. 19 to 21 are schematic cross-sectional views of the semiconductor device at various stages. FIG. 18B is a schematic top view of the semiconductor device and FIG. 18A is taken along a line A-A′ of FIG. 18B. It must be noted here that the embodiment in FIGS. 2 to 17, FIG. 18A, FIG. 18B and FIGS. 19 to 21 continues to use the referential numbers of the elements and a part of the contents of the embodiment of FIG. 1, wherein the same or similar referential numbers are used to denote the same or similar elements, and the description of the same technical contents is omitted. For the description of the omitted part, reference may be made to the foregoing embodiments, and details are not repeated here. Besides, for clarity, FIG. 18B only illustrates the word lines 134 and the openings OP4, and omits other components.

Referring to FIG. 2, shallow trench isolations 102 are formed in the semiconductor substrate 100. For example, trenches (not shown) are first formed in the semiconductor substrate 100 by photolithography and etching processes. Then an oxide material (such as silicon oxide or the like) is deposited in the trenches and on the semiconductor substrate 100. A planarization process may be performed to remove excess oxide material disposed on the top surface of the semiconductor substrate 100 to form the shallow trench isolations 102.

Continuing referring to FIG. 2, active devices 104 are formed on the semiconductor substrate 100. For example, a gate oxide material layer, a gate material layer and a hard mask material layer are sequentially deposited on the semiconductor substrate 100. Then, the gate oxide material layer, the gate material layer and the hard mask material layer are patterned by photolithography and etching processes to form a gate oxide layer 105a, a gate 105b and a hard mask layer 105c. The gate oxide layer 105a, the gate 105b and the hard mask layer 105c are collectively referred to a gate stack 105. Then, a sidewall spacer 106 is formed on the sidewall of the gate stack 105. Based on the above, the active device 104 is substantially formed. In some embodiments, the material of the gate oxide layer 105a includes silicon oxide or other suitable conductive materials. In some embodiments, the material of the gate 105b includes metals (such as Cu, W, Al, Ti, alloy thereof, or the like), poly silicon, a combination thereof or other suitable conductive materials. In some embodiments, the material of the hard mask layer 105c includes silicon nitride or other suitable conductive materials.

Continuing referring to FIG. 2, a dielectric layer 108 is deposited on the active devices 104 and the semiconductor substrate 100 and conductive contacts 109 are formed in the dielectric layer 108. The conductive contacts 109 may include source contacts, drain contacts and gate contacts, which electrically connect between the interconnect structure and the source, drain or gate of the active device 104. In some embodiments, the material of the dielectric layer 108 includes silicon oxide or other suitable conductive materials. In some embodiments, the material of the conductive contacts 109 includes Cu, W, Al, Ti, alloy thereof or other suitable conductive materials.

Continuing referring to FIG. 2, an interconnect structure 110 is formed on the dielectric layer 108. For example, a conductive layer 112 is formed on the dielectric layer 108 and patterned. Then, a dielectric layer 111 is deposited on the conductive layer 112 and patterned. Repeating the aforementioned steps until the number of the conductive layer 112 is achieved, and thereby the interconnect structure 110 is formed.

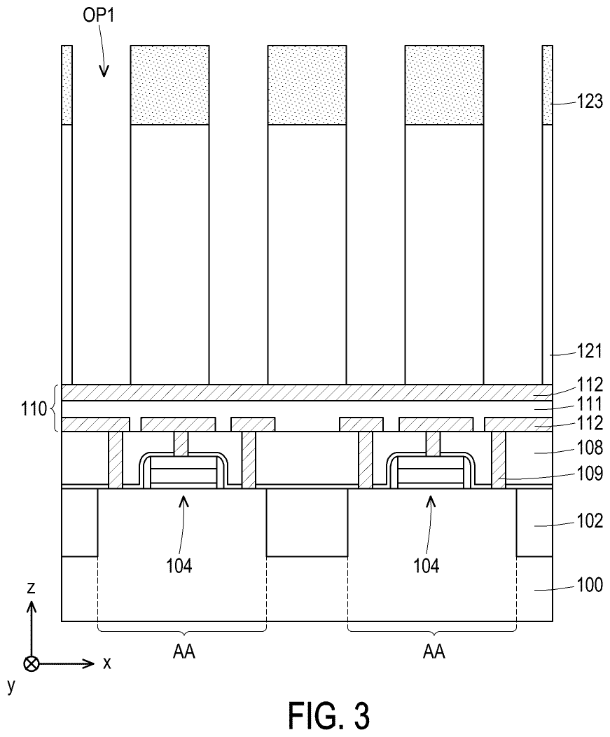

Referring to FIG. 3, a dielectric layer 121 and a hard mask layer 123 are sequentially deposited on the interconnect structure 110 and then patterned by photolithography and etching processes to form openings OP1 in the dielectric layer 121 and the hard mask layer 123. In some embodiments, the material of the dielectric layer 121 includes silicon oxide or other suitable conductive materials. In some embodiments, the material of the hard mask layer 123 includes silicon nitride or other suitable conductive materials.

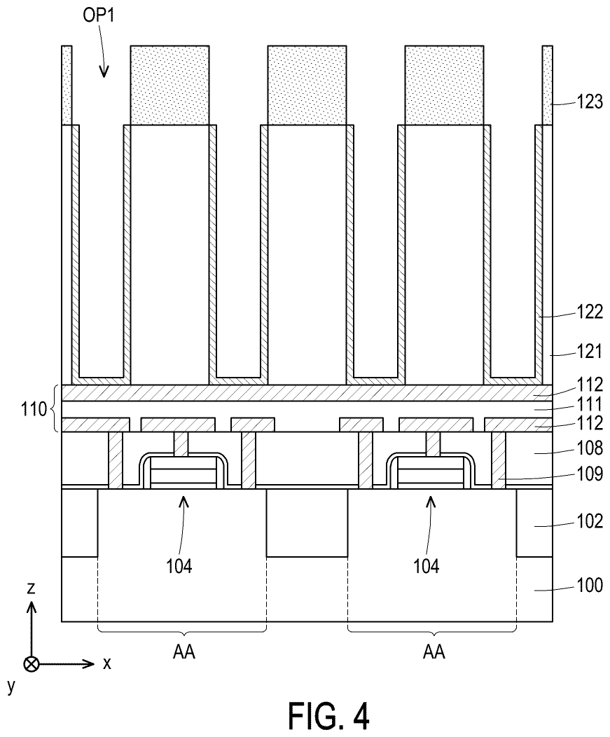

Referring to FIG. 4, bottom electrodes 122 are formed in the openings OP1. For example, a conductive material layer is first conformally deposited on the top surface of the hard mask layer 123, sidewalls of the openings OP1 and the exposed surfaces of the conductive layer 112 by atom layer deposition, chemical vapor deposition, physical vapor deposition or other suitable methods. Then, a photoresist material (not shown) is filled in the openings OP1 to cover the conductive material layer in the dielectric layer 121. An etching process is performed to remove the conductive material layer not covered by the photoresist material, so that the remaining conductive material layer forms the bottom electrode 122. Afterwards, the photoresist material is removed from the openings OP1. In some embodiments, the material of the bottom electrodes 122 includes metal nitrides (such as TiN or the like) or other suitable conductive materials.

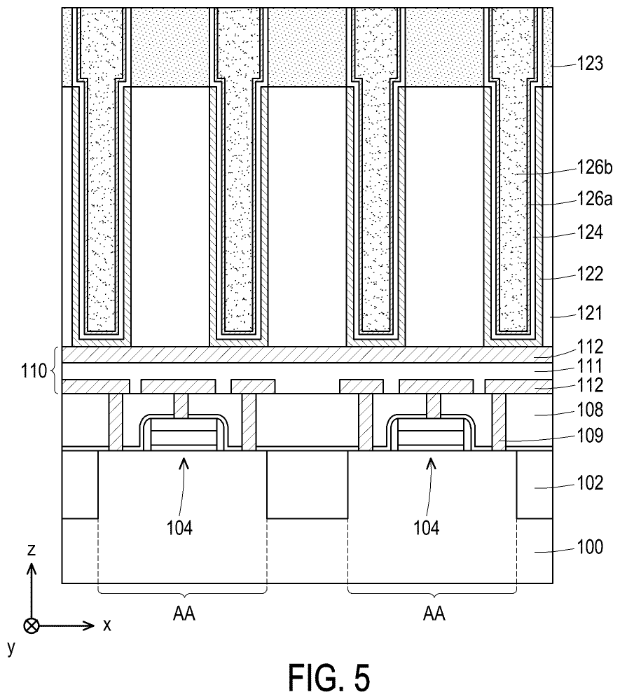

Referring to FIG. 5, an insulator 124 is conformally formed in the openings OP1 and on the bottom electrode 122 by atom layer deposition, chemical vapor deposition, physical vapor deposition or other suitable methods. In some embodiments, the material of the insulator 124 includes silicon oxide or other suitable conductive materials. Then, a first conductive layer 126a is conformally formed in the openings OP1 and on the insulator 124 by atom layer deposition, chemical vapor deposition, physical vapor deposition or other suitable methods. Thereafter, a second conductive layer 126b is filled in the openings OP1 by atom layer deposition, chemical vapor deposition, physical vapor deposition or other suitable methods. In some embodiments, a planarization process is performed to remove excess insulator 124, excess first conductive layer 126a and/or excess second conductive layer 126b formed on the top surface of the hard mask layer 123. In some embodiments, the material of the first conductive layer 126a includes metal nitrides (such as TiN or the like) or other suitable conductive materials. In some embodiments, the material of the second conductive layer 126b includes poly silicon or other suitable conductive materials.

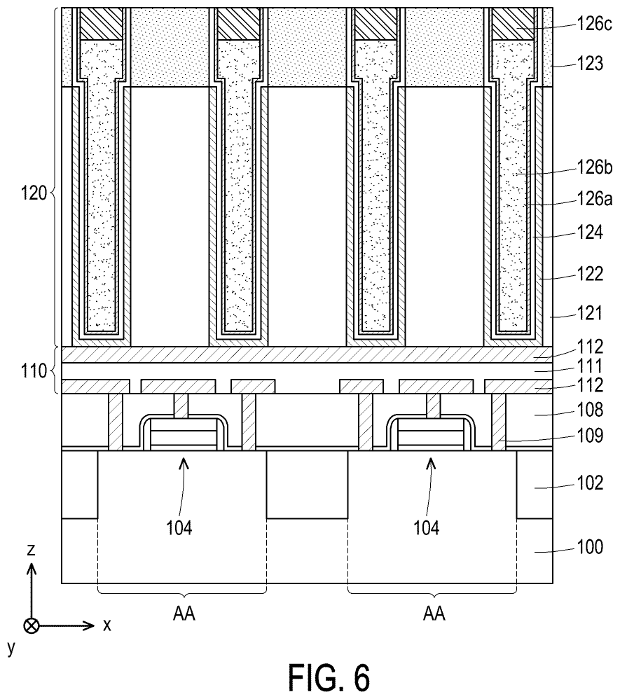

Referring to FIG. 6, an etching process (such as a dry etching process or a wet etching process) is performed to remove a portion of the second conductive layer 126b to form a recess (not shown) in the second conductive layer 126b. Then, a conductive material is formed in the recess and on the hard mask layer 123. A planarization process is performed to remove excess conductive material formed on the hard mask layer 123 and the remaining conductive material formed in the recess of the second conductive material 126b forms the third conductive layer 126c. In some embodiments, the conductive material of the third conductive layer 126c includes conductive oxides (such as indium tin oxide (ITO) or the like) or other suitable conductive materials.

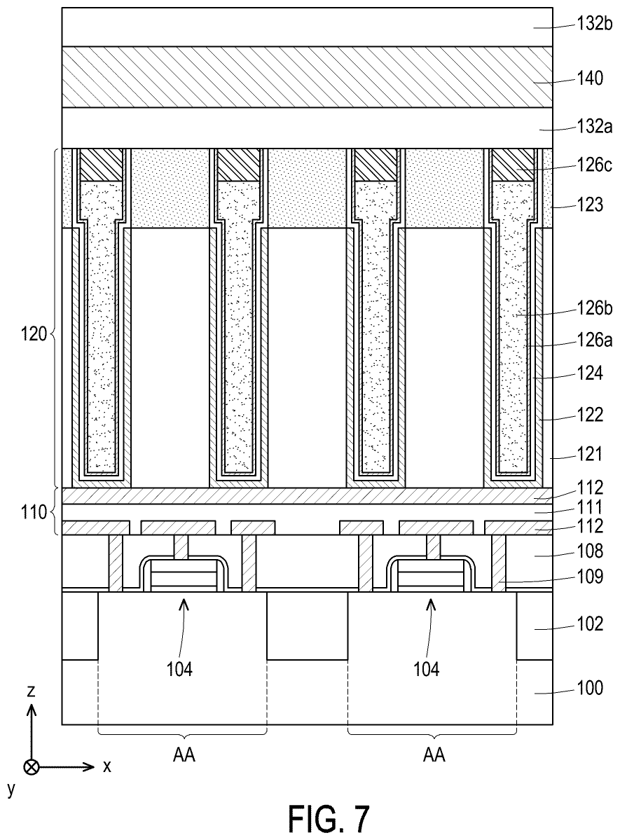

Referring to FIG. 7, a dielectric material layer 132a, a gate material layer 140 and a dielectric material layer 132b are sequentially deposited on the hard mask layer 123 by chemical vapor deposition, physical vapor deposition, atom layer deposition or other suitable methods. In some embodiments, the material of the dielectric material layer 132a and the dielectric material layer 132b include silicon oxide or other suitable conductive materials. In some embodiments, the material of the gate material layer 140 includes Cu, W, Al, Ti, alloy thereof, or other suitable conductive materials.

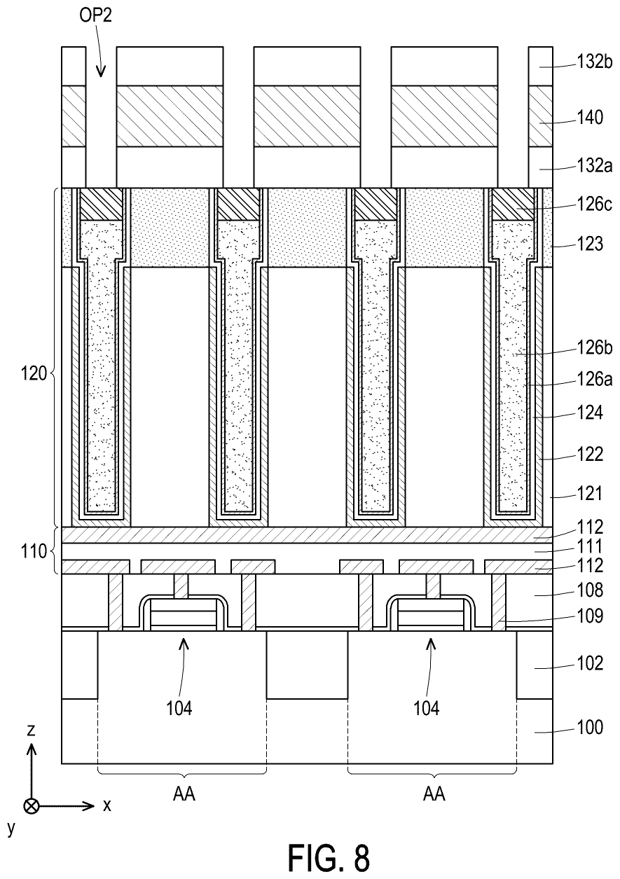

Referring to FIG. 8, openings OP2 are formed in the dielectric material layer 132a, the gate material layer 140 and the dielectric material layer 132b by one or more etching processes to expose the third conductive layer 126c.

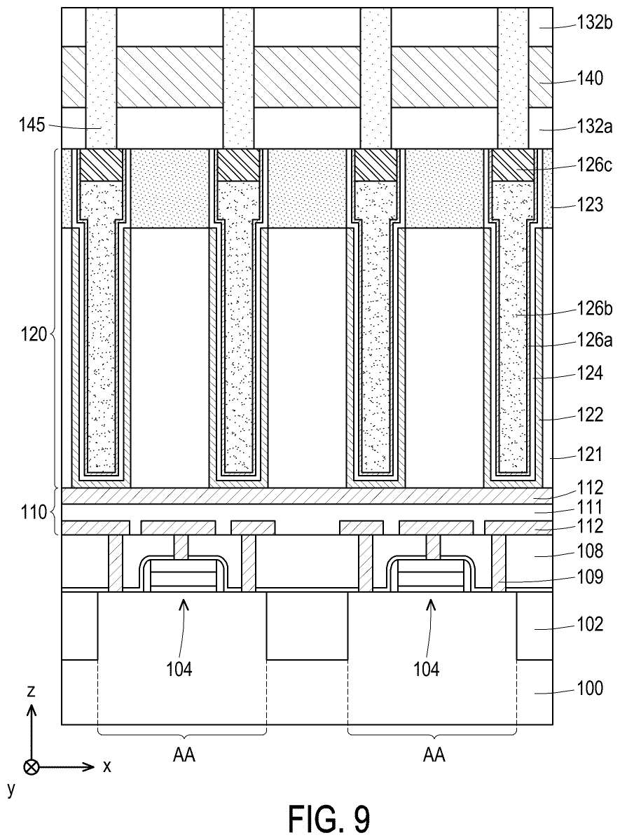

Referring to FIG. 9, a sacrificial layer 145 is formed in the openings OP2 and on the top surface of the dielectric material layer 132b. Then, the sacrificial layer 145 is etched back to remove a portion of the sacrificial layer 145 formed on the top surface of the dielectric material layer 132b. In some embodiments, a material of the sacrificial layer 145 includes poly silicon or other suitable materials.

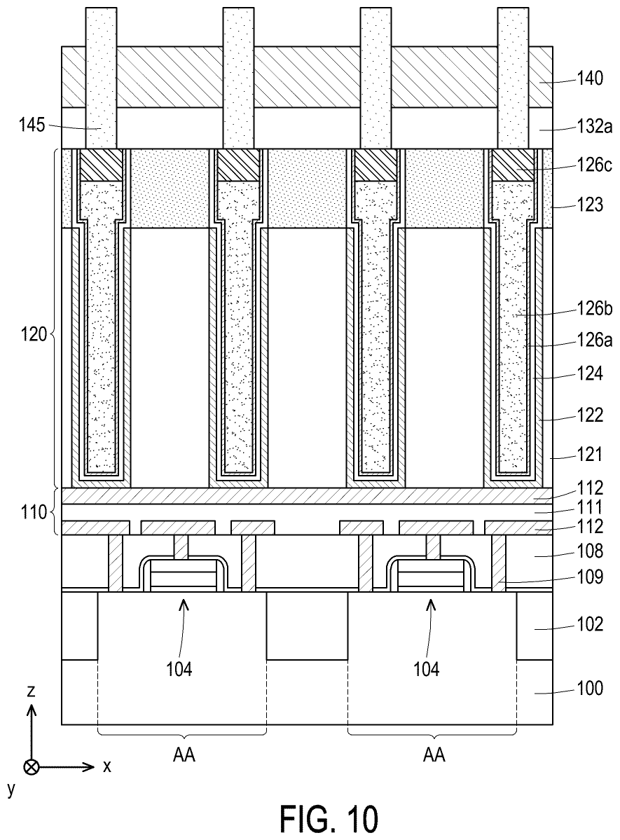

Referring to FIG. 10, an etching process (such as a wet etching process or the like) is performed to remove the dielectric material layer 132b, so that a portion of the sidewalls of the sacrificial layer 145 is exposed.

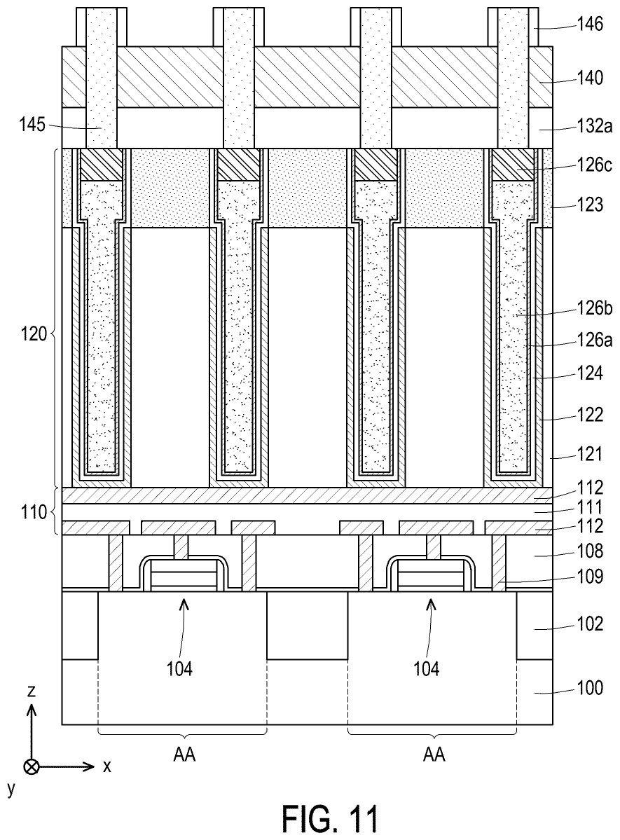

Referring to FIG. 11, sidewall spacers 146 are formed on the exposed sidewalls of the sacrificial layer 145. In some embodiments, a material of the sidewall spacers 146 includes silicon oxide or other suitable materials.

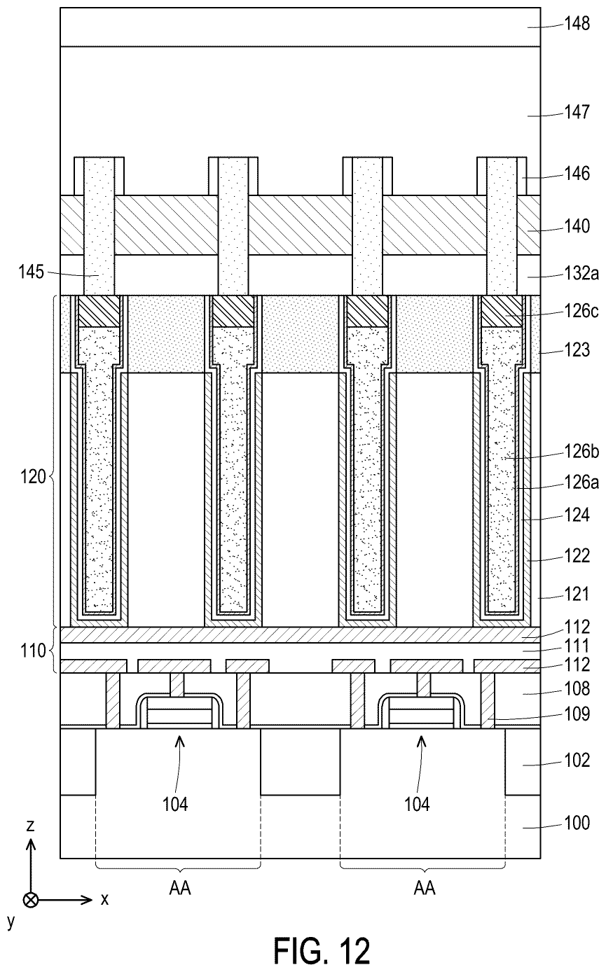

Referring to FIG. 12, a mask layer 147 is formed on the sacrificial layer 145 and the gate material layer 140, and a mask layer 148 is formed on the mask layer 147. In some embodiments, a material of the mask layer 147 includes carbon or other suitable materials, and a material of the mask layer 148 includes silicon nitride or other suitable materials.

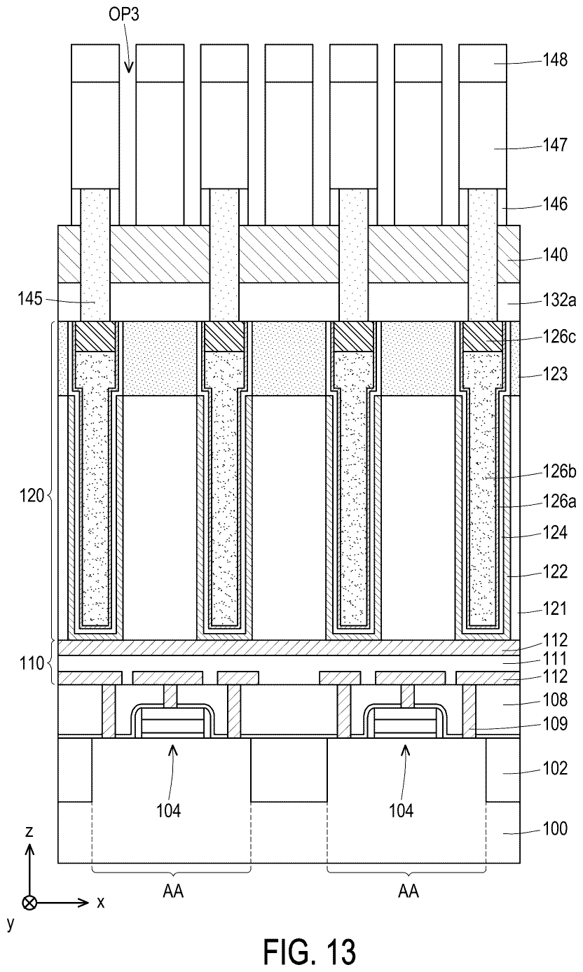

Referring to FIG. 13, opening OP3 are formed in the mask layer 147 and the mask layer 148. For example, the mask layer 148 is patterned by photolithography and etching processes (such as a dry etching process). Then, using the patterned mask layer 148 as an etch mask, the mask layer 147 is patterned by an etching process to expose a portion of the gate material layer 140.

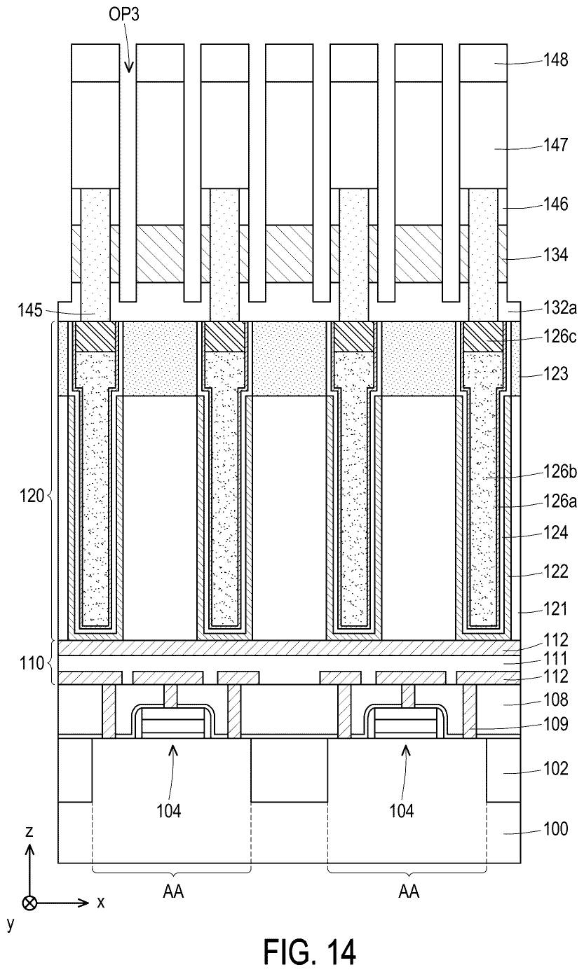

Referring to FIG. 14, using the patterned mask layer 148 and patterned mask layer 147 as an etch mask, the gate material layer 140 is patterned by an etching process (such as a dry etching process) to expose a portion of the dielectric layer 132a. The remaining gate material layer 140 forms the word lines 134. In some embodiments, during the etching process, a portion of the exposed dielectric layer 132a is removed.

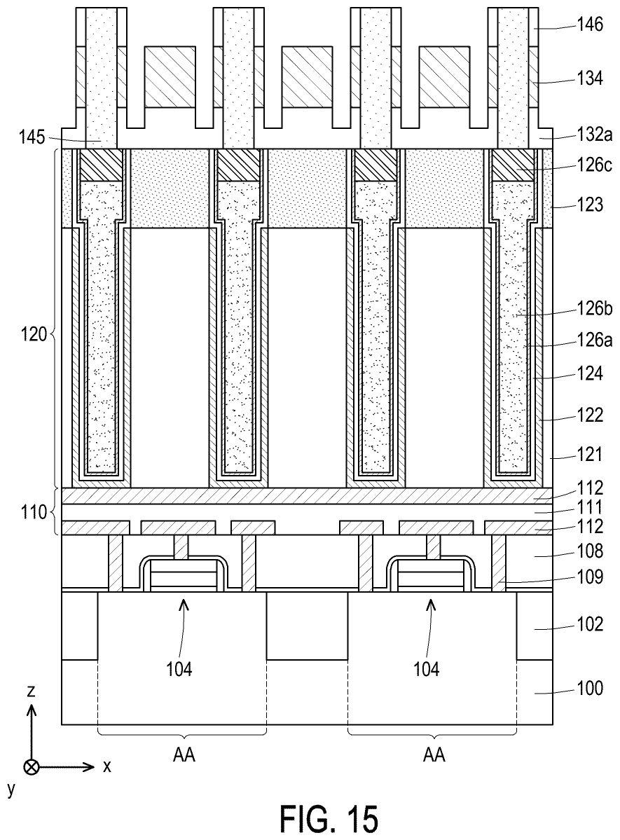

Referring to FIG. 15, the mask layer 147 and the mask layer 148 are stripped away, so that the word lines 134 are exposed.

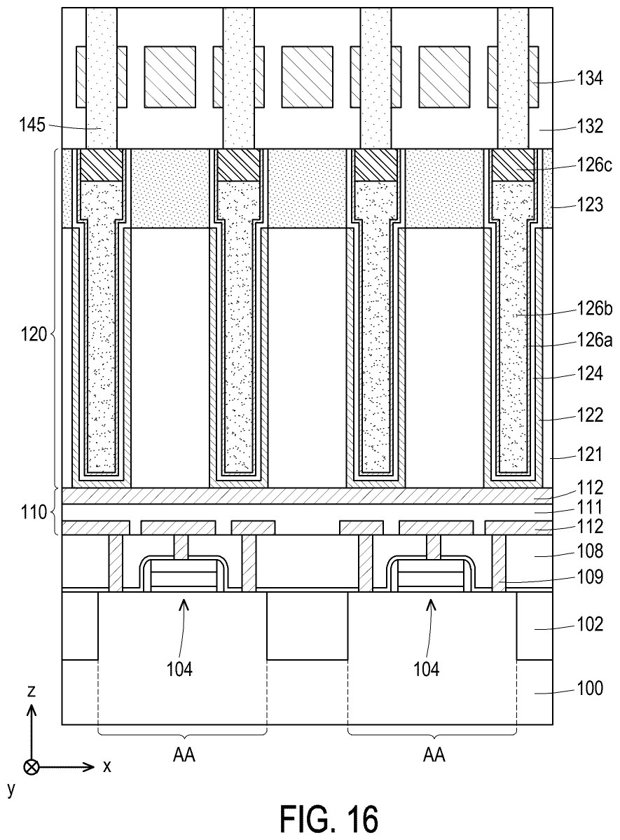

Referring to FIG. 16, a dielectric material layer is deposited on the word lines 134 and the sacrificial layer 145 by chemical vapor deposition, physical vapor deposition, atom layer deposition or other suitable methods. In some embodiments, a material of the dielectric material layer includes silicon oxide or other suitable materials. Then, a planarization process is performed to remove the dielectric material layer until the sacrificial layer 145 is exposed. The remaining dielectric material layer and the dielectric layer 132a collectively forms the dielectric layer 132.

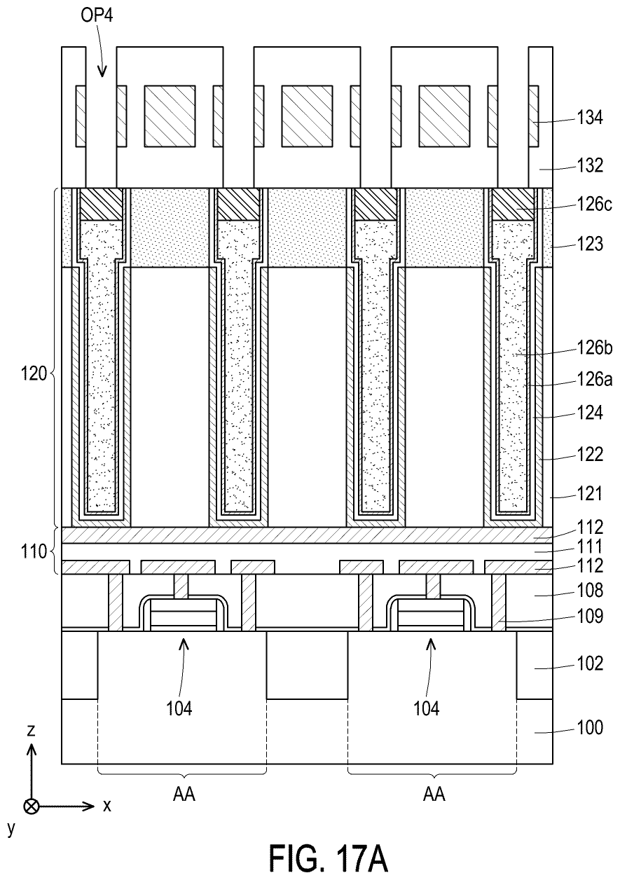

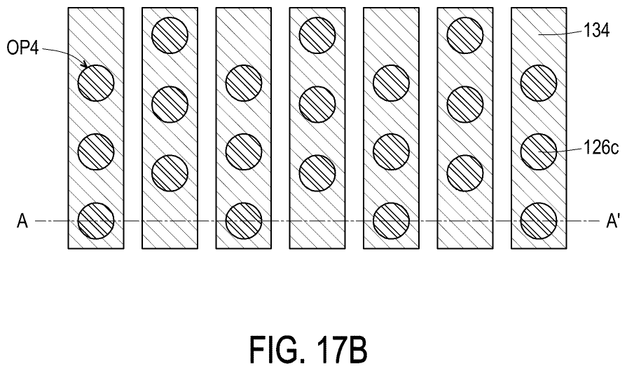

Referring to FIG. 17A and FIG. 17B, the sacrificial layer 145 is removed by for example an etching process to form openings OP4 in the dielectric layer 132 and the word lines 134. As shown in FIG. 17B, the openings OP4 formed in adjacent word lines 134 are staggered with each other.

Referring to FIG. 18, a gate dielectric layer 142 is formed in the openings OP4. For example, a gate dielectric material is conformally deposited on the top surface of the dielectric layer 132 and sidewalls and bottom surfaces of the openings OP4 by atom layer deposition, chemical vapor deposition, physical vapor deposition or other suitable methods. Then an etching process is performed to remove the gate dielectric material formed on the bottom surfaces of the opening OP4, so that the top surfaces of the third conductive layer 126c are exposed and the remaining gate dielectric material forms the gate dielectric layer 142.

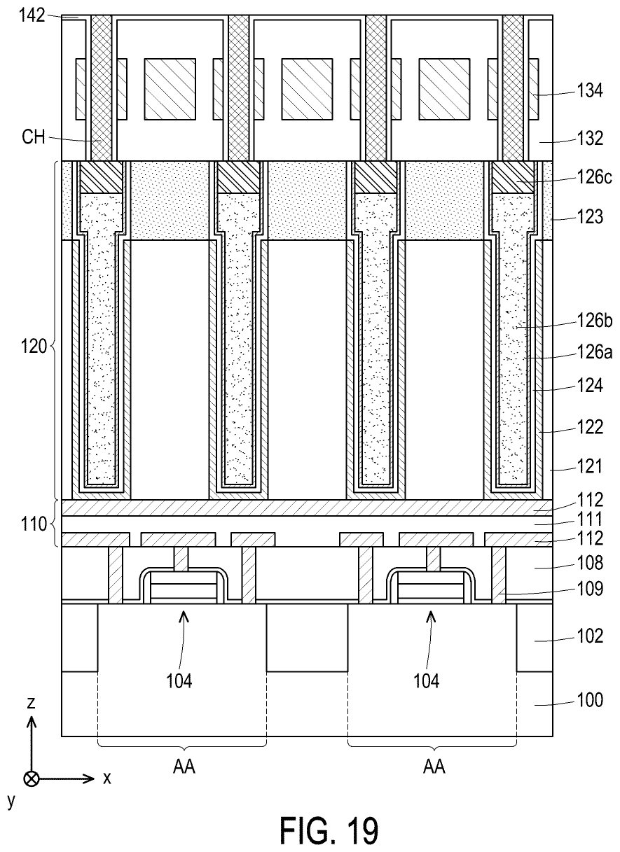

Referring to FIG. 19, channel structures CH are formed in the openings OP4. For example, a channel material is filled in the openings OP4 and on the top surface of the dielectric layer 132. Then an etching process is performed to remove a portion of the channel material formed on the top surface of the dielectric layer 132, and the remaining channel material in the opening OP4 forms the channel structures CH. In some embodiments, a material of the channel structures CH or the channel material includes semiconductor oxide, for example, indium gallium zinc oxide (IGZO) or the like.

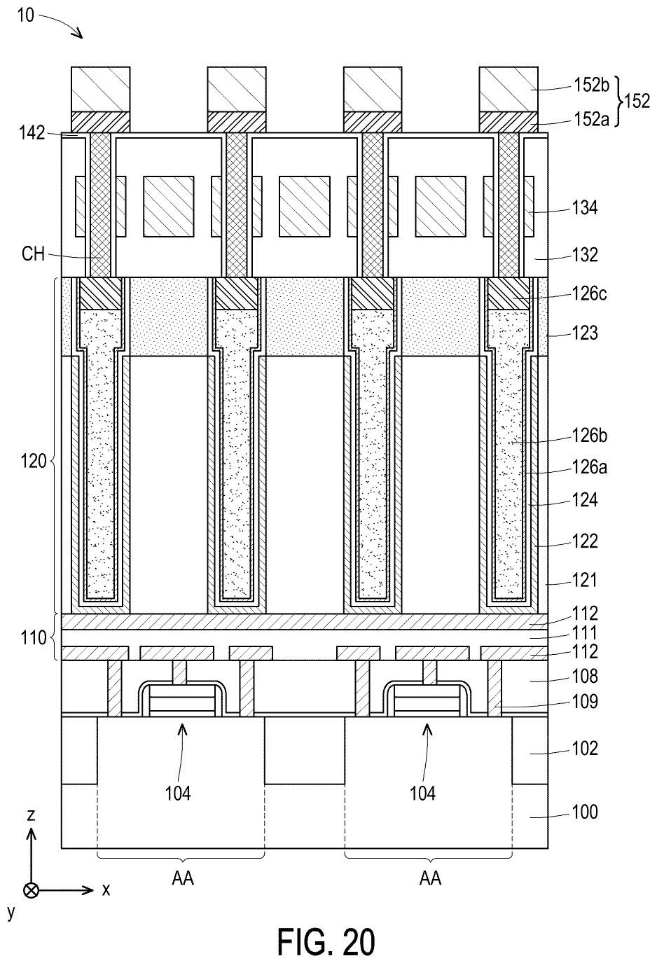

Referring to FIG. 20, landing pads 152 are formed on the channel structures CH. For example, a first conductive material layer and a second conductive material layer are formed on the dielectric layer 132 and patterned to form a first conductive layer 152a and a second conductive layer 152b. The first conductive layer 152a and the second conductive layer 152b collectively forms landing pads 152.

Based on the above, the semiconductor device 10 is substantially formed.

The present invention includes a capacitor structure between the plurality of word lines and the semiconductor substrate. Since the plurality of word lines is disposed over the capacitor structure, some peripheral circuits or core circuits of the semiconductor device could be formed between the semiconductor substrate and the capacitor structure to make efficient use of space, and thereby the size of the semiconductor device can be reduced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a semiconductor substrate;
a capacitor structure disposed over the semiconductor substrate; and
a word line disposed above the capacitor structure.

2. The semiconductor device of claim 1, further comprising:
a channel structure disposed on the capacitor structure.

3. The semiconductor device of claim 2, wherein a material of the channel structure comprises a semiconductor oxide.

4. The semiconductor device of claim 2, further comprising:
a gate oxide layer disposed between the word line and the channel structure.

5. The semiconductor device of claim 2, wherein the channel structure extending through the word line.

6. The semiconductor device of claim 2, wherein an extension direction of the channel structure is perpendicular to a top surface of the semiconductor substrate.

7. The semiconductor device of claim 2, wherein the channel structure is in direct contact with a top electrode of the capacitor structure.

8. The semiconductor device of claim 7, wherein the top electrode of the capacitor structure comprises a conductive oxide layer.

9. The semiconductor device of claim 2, further comprising:
a landing pad disposed over the word line, wherein the channel structure is connected between the landing pad and the capacitor structure.

10. The semiconductor device of claim 9, wherein the landing pad comprises a conductive oxide layer.
